(19) United States
(12) Patent Application Publication
(10) Pub. No.: US 2013/0257468 A1
(43) Pub. Date: Oct. 3, 2013

(54) Stackable Electromagnetically Isolated Test Enclosures

(71) Applicant: OCTOSCOPE INC., Bolton, MA (US)

(72) Inventor: Fanny Mlinarsky, Bolton, MA (US)

(73) Assignee: octoScope Inc., Bolton, MA (US)

(21) Appl. No.: 13/856,356

(22) Filed: Apr. 3, 2013

Related U.S. Application Data
(60) Provisional application No. 61/619,714, filed on Apr. 3, 2012.

(51) Int. Cl. G01R 1/18

(52) U.S. Cl. CPC G01R 1/18
USPC 324/750.27

(57) ABSTRACT

The present disclosure is directed to systems and methods for operating, designing, testing and verifying the performance of wireless communication devices. Specifically, the present systems and methods can reliably emulate a mobile environment with channel impairment in an ad-hoc network and determine the operating behavior (routing, auto-healing, etc.) of wireless communication modules. Utilizing a relatively inexpensive, compact testing chamber arrays with useful electromagnetically isolating structure, the present invention allows for scalable, multi-application and production line operation and testing and verification of electromagnetic equipment therein.

### CROSS REFERENCE TO RELATED APPLICATIONS

This application incorporates by reference the entire contents of the co-pending U.S. patent application Ser. No. 13/195,097, filed on 11 Aug. 2011 entitled “Electromagnetic Test Enclosure,” and also claims priority to and is a non-provisional of U.S. Provisional Application Ser. No. 61/619,714 entitled “Stackable Electromagnetically Isolated Test Enclosures.” The entire teachings of the above referenced applications are incorporated herein by reference.

### TECHNICAL FIELD

The present application relates to design and testing of electromagnetic communication systems. More particularly, relating to compact enclosures for the same in the context of operation, design and testing of mobile ad-hoc networking components and devices. In some aspects the compact enclosures are modular and may be coupled or positioned with respect to one another in a configurable arrangement.

### BACKGROUND

Wireless communication has grown to encompass a huge variety of information transactions between electronic machines. These include cellular communications between hand-held units and base stations, wireless communications between peer devices or master-servant components, and even between components on a same device.

For reliable interoperability, wireless communications have been organized into known formats, generally referred to by the associated protocols, so that multiple parties can communicate effectively using compatible communication devices and methods. This encompasses communications between devices employing same communication protocols but made by different manufacturers in different parts of the world. In some respects, these protocols determine the allowable or preferred techniques for delivering and interpreting data communicated between a plurality of communication devices. In other respects, the protocols govern the way in which information is packaged for transmission over conducting or optical lines or over the air (OTA) in a wireless communication environment.

Furthermore, governmental agencies impose regulations controlling the allowable quality and environmental impact of wireless communications. These regulations may be mandated and/or required for public sale and use of the devices. Testing of such devices is difficult in small, enclosed spaces. That is, enclosed spaces typically do not provide far-field spacing between the elements that are in communication with one another.

Dimensionally, this deficiency is compounded by the production of electromagnetic standing wave modes, depending on test device frequency and geometry of the test enclosure. Standing wave modes and associated reflections generate impermissible errors by affecting test conditions. In particular, results may be dependent on where a device under test (DUT) is disposed in the test enclosure—whether near a peak or null.

Testing of wireless electronic communication products and systems allows for determination of the performance of the communication features of the products and systems. This can permit better design of the wireless components to prevent or minimize the effects of “dead zone” or fade-out or other poor performance problems encountered in many wireless communication products.

Present systems for designing and testing of wireless products lack flexibility, are too costly to make and operate, take up too much space, and generally cannot flexibly permit the testing of the variety and number of devices as described herein.

Other shortcomings of current test systems include that they generally are carried out in a “conducted” test fashion, where the antenna of the device under testing is bypassed. While this improves repeatability, it does not fully capture the real world performance of the device, as the test is conducted without the use of the antenna, which is an important element of the wireless communication system.

Additionally, in the context of a network, software is often used to simulate changing conditions affecting signal pathway, throughput, path loss, dynamic range, roaming, and transmission rate/MCS adaptation. These systems are not suited for accurate testing of said parameters in a plurality of wireless modules within a network.

Current systems are also not adapted for testing multiple electromagnetic (e.g., radio, RF) communication modalities within a single device. Some present test facilities are poorly isolated from the outside environment. As a result, to compensate for this weakness, many measurements are taken on a device under test and an averaging or statistical result is deduced from the many measurements, therefore taking a longer time to test a single device.

There are a number of different circumstances in which it is desirable to perform testing and analysis to identify the efficiency of mobile ad-hoc networks. Presently, motion and channel impairment is simulated in a mobile ad-hoc network using in a software environment producing artifacts and unnecessary path switching leading to additional hops and/or timeouts. There exists, a demand for low cost, compact, low-power, accurate, easy to use, and reliable test environment test environment capable of emulating motion and channel impairment within an ad-hoc network.

Additionally, current systems do not permit production line testing in any meaningful or efficient way. That is, current testing environments and systems and methods are not scalable for efficient or economical production line testing.

### SUMMARY

As mentioned above, the present inventions related to new and improved systems and methods for operating, designing, testing and verifying the performance of wireless communication devices. Specifically, the present systems and methods can reliably determine the operating behavior of wireless communication modules within electronic products and devices. This includes the ability to reliably and repeatedly test the effectiveness of radio frequency (RF), 802.11, cellular, 3G, 4G/LTE, WiMax, Bluetooth, microwave and other electromagnetic receiver, transmitter and transceiver components.

In some aspects, the present systems provide relatively compact enclosures for performing the above design and testing. The enclosures are preferably relatively mobile and small in size compared to typical existing over-the-air (OTA) testing facilities, which are usually room-sized or laboratory-sized and not mobile. The enclosures are also preferably provide isolation from RF, microwave and other electromagnetic interference so that the testing conducted within the enclosures is substantially performed without such interference.

In other aspects, the present enclosure systems are geometrically and operationally adaptable for a variety of applications and uses, as will be explained below. In all, the present testing chambers and the methods for using the same allow for better design of electromagnetic wireless communication systems and components.

In still other aspects, the present systems and methods permit more reliable, repetitive, and production scale testing of said wireless systems. In still other aspects, the present systems and methods permit the testing of an ad-hoc network emulating nodal movement and resultant impairment wherein a plurality of different electromagnetic receivers and transmitters are designed to co-exist and, in some embodiments, interdepend within a network.

In some applications, the electromagnetic test chambers are configured to be stackable or configurable with respect to one another in a system of multiple test chambers containing electromagnetic devices. Such systems of multiple interrelated test chambers may be adapted for mechanical and/or electrical arrangement with respect to one another suiting a given experiment, test or use.

### IN THE DRAWINGS

FIG. 1 illustrates an exemplary isometric view of a wireless test chamber for testing of one or more wireless devices;

FIG. 2 illustrates an exemplary view of a wireless test chamber, as viewed from the front;

FIG. 3 illustrates an exemplary view of a wireless test chamber from a right side perspective;

FIG. 4 illustrates an exemplary view of a wireless test chamber from a left side perspective;

FIG. 5 illustrates an exemplary rear view of a wireless test chamber;

FIG. 6 illustrates an exemplary top-down perspective of a wireless test chamber;

FIG. 7 illustrates an isometric view of an exemplary arrangement of a plurality of test enclosures in mechanical and cabled signal communication with one another;

FIG. 8 illustrates an exemplary top-down view of an arrangement of a plurality of wireless test enclosures;

FIG. 9 illustrates an exemplary bottom view of an arrangement of a plurality of wireless test enclosures;

FIG. 10 illustrates a heuristic electrical block diagram for mesh testing a plurality of wireless communication devices within a controlled environment;

FIG. 11 illustrates an isometric view of an exemplary test chamber depicting an internal configuration;

FIG. 12 illustrates an exemplary test chamber in an alternate embodiment; and

FIG. 13 illustrates an exemplary matrix module used in mesh testing, in one or more embodiments.

### DETAILED DESCRIPTION

As mentioned above, the present inventions related to new and improved systems and methods for operating, designing, testing and verifying the performance of wireless communication devices. Specifically, the present systems and methods can reliably determine the operating behavior of wireless communication modules within electronic products and devices. This includes the ability to reliably and repeatedly test the effectiveness of radio frequency (RF), 802.11, cellular, 3G, 4G/LTE, WiMax, Bluetooth, microwave and other electromagnetic receiver, transmitter and transceiver components, either individually and/or in a real or emulated network.

In some embodiments, the present systems provide relatively compact enclosures for performing the above design and testing. The enclosures are preferably relatively mobile and small in size compared to typical existing over-the-air (OTA) testing facilities, which are usually room-sized or laboratory-sized and not mobile. The enclosures also preferably provide isolation from RF, microwave and other electromagnetic interference so that the testing conducted within the enclosures is substantially performed without such interference. The enclosures are additionally, in some embodiments, geometrically and operationally adaptable for a variety of applications and uses, as will be explained below.

At minimum, the present testing chambers and the methods for using the same allow for better design of electromagnetic wireless communication systems, components, and networks. Also, the present systems and methods permit more reliable, repetitive, and production scale testing of said wireless systems.

In some aspects, the present systems and methods permit the testing and emulation of mobile networks. In one or more embodiments, the present testing chambers may be stacked and in electrical communication with one another, each representing a node disposed in an ad-hoc network, wherein a plurality of different electromagnetic receivers and transmitters are designed to co-exist and, in other aspects, interdepend on one another within an emulated mobile network.

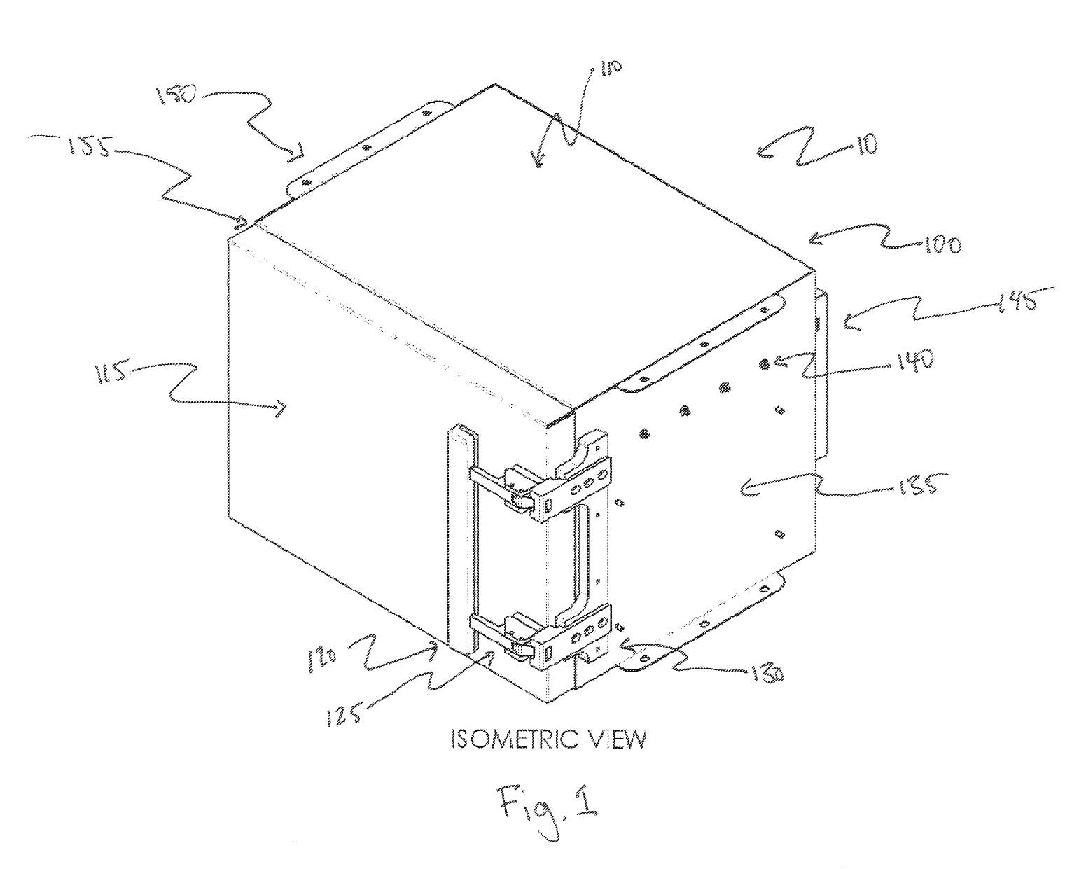

FIG. 1 illustrates an isometric view of an exemplary electromagnetic test enclosure system 10 that can be used for the above purposes to design or test electromagnetic devices (e.g., the performance of transmitting and/or receiving components and antennae). Such a system is herein referred to as a test enclosure though it is to be understood that testing an apparatus or component is but one use of the present system. Other purposes and uses include verification, design, analysis, scientific experimentation, proving or confirming compliance, certification, adaptation manipulation, throughput maximization, least hop detection, network awareness, power transmission minimization, mass production or production line testing, and others.

Electromagnetic test enclosure system 10 is comprised by a housing 100, which may be formed of one or more individual housing parts, and a door 115. In the embodiment shown, the housing 100 and door 115 are mechanically coupled structures make up the enclosure space of the test enclosure system 10. Both coupled components, housing 100 and door 115, are made of walls that substantially isolate the electromagnetic environment on either side of said walls, and are constructed of electromagnetically opaque materials (e.g., metal, alloy, or other conducting solids such as steel in some embodiments). That is, an inside or internal volume is defined and an outside or external volume is defined by said walls.

In the present embodiment, this is performed by outer wall construction using a material with very high conductivity, sigma, with a thickness greater than the skin depth, delta, for a given electromagnetic wave. As is known in the art, a material with an infinite conductivity reflects all electromagnetic waves impinge its surface, evanescence notwithstanding. In practice, the purpose of the highly conductive material prevents electromagnetic interference from entering the test chamber.

The interior surfaces of the compartments of the test system may be made substantially or partially anechoic so as to absorb or minimize the internal reflection of electromagnetic waves incident upon said internal walls. One or more embodiments, this is accomplished by lining the interior with a lossy material of complex impedance. As known in the art, the real part of a refractive index (as in the optical bandwidth of the electromagnetic spectrum) bestows boundary conditions governing refection and transmission, while the imaginary part imparts absorption for a given wavelength. Analogous parameters are known in the RF regime: attenuation constant, loss tangent in dielectrics, etc.

Layering lossy material in a gradient also reduces reflections back into the test chamber. Beginning with a material with an impedance close to that of free space (i.e., impedance matching), maximizes the transmission of the imparted electromagnetic signal into the damping material. Cascading materials of higher and higher impedance results in wave propagation radially, away from a DUT and towards the outer walls, whereby it is reflected back through the material gradient thereby attenuating signal power. In other embodiments and not beyond the scope of the present invention, this can be accomplished quarter or half wave plate rectifiers, such as Fabry-Perot filters, to preclude any reflections for a given carrier frequency.

In similar construction, one or more of the faces of the enclosure (e.g. a front face) generally has a door 115 that can open and shut for access to the inside of the enclosure. The door or doors are made of electromagnetically opaque material (e.g., steel) are mounted to corresponding hinges, depicted later, that rotate on an axis to permit secure shutting of the doors and electromagnetic isolation of the internal environment volume when the doors are shut.

An operator (human or robot machine) may place the one or more DUT devices, not shown, into the enclosure comprised by the housing 100. The door opening 155 may be surrounded by a suitable electromagnetically-tight isolating strip, lip, bevel, chamfer, or gasket that prevents small amounts of radiation from leaking in or out of the areas surrounding the doors when shut. The tightness and isolating capabilities of the doors are further enhanced by the use of secure latches 130 to hold the doors shut when testing is in progress. A warning light may indicate when testing is in progress so that an operator does not accidentally open the enclosure doors and defeat the isolating function thereof.

The doors of the enclosures of the present test system may swing open or shut on hinges as will be shown in later. Alternatively, the doors of the enclosures of the present system may slide on rails, slots, guides or other linear members so that the doors can open and shut securely to expose the interiors of the enclosures when the doors are open and isolate the interior volumes when the doors are shut. The door to a given enclosure may comprise only one panel or it may comprise a plurality (e.g., two) panels that cooperatively move together to open or shut the door to the enclosure. Still alternatively, a door to an enclosure may swing on a pivot upward and outward in a direction parallel to the face of the enclosure wall (fan-like), or in a direction perpendicular to the face of the enclosure wall (gull-wing door style). Accordion style doors, doors that move like those of a conventional garage door and other door styles are also possible for use with the proper materials and mechanical articulation elements as suits a given application.

Referring to FIG. 1, the housing 100 is comprised by chamber roof 110, communication port wall 135, another wall disposed distally from said communication port wall 135, a rear wall disposed adjacent to same, and test chamber floor, as described later in the present application. All components comprising housing 100 are made from anechoic and electromagnetic shielded/insulated materials. For proper securement of the test chamber door 115, a robust handle 120 is used in conjunction with latching mechanism 125, which is fastened to housing via brackets 130. As will be discussed, test chamber are stacked in practice and secured together with fasteners 150.

The test chamber 145 holds an electromagnetic antenna, as described in more detail below, to be in electrical communication by way of a conducting line, coaxial cable, or other connection. A device under testing (DUT) may be disposed in the test chamber 100 for over the air (OTA) testing and communication with electromagnetic antenna, detailed later.

In one or more present embodiments, a plurality of individual DUT devices may be placed in the test chamber. The plurality of individual DUT devices can include a plurality of identical device in the context of testing in production environments to increase the throughput of the production line testing.

While the a plurality of compartments or test chambers have been illustrated as being one on top of the other, in a given implementation, it may not critically matter if the stack compartments or test chambers are placed above one another, side-by-side, front-to-back, or in another reasonable configuration.

In basic operation, the system 10 allows for wireless electromagnetic communication between a wireless component (linker matrix module; described in more detail later) that can be controlled by a master device, either implemented in software or hardware, and in electrical communication with a device under testing (DUT). Various DUT devices may be interchangeably placed in the shielded space in the present enclosure and tested as to the performance of their wireless communication modules and features. This includes testing the multi-modal communication features or MIMO features thereof.

One or more sensor test probes or antennae may be introduced into the test enclosure 145 to make measurements of the electromagnetic field at a location of the one or more test probes or antennae. In other embodiments, manual or automated translation and/or rotation or repositioning of any of the DUT or sensor probes or antennae can be used to map out a two- or three-dimensional representation of a characteristic (e.g., strength, intensity) of the electromagnetic field within the enclosure.

In some embodiments, the compartment or test chamber 100 is longer in one dimension than in the others. For example, in an upright format as shown in the present example, the test chamber is wider than it is tall or deep to ensure far field geometries. In this way, the overall dimensions of the system 10 can be kept relatively small and compact, but a long dimension can be maintained that allows for far-field communication between the DUT and the antenna disposed in said test chamber 145.

In such a system a positioning apparatus or positioning rack may be included to allow relative movement and positioning of the DUT with respect to the antenna. In this way, while only one dimension of the compartment 100 is sufficiently long to provide the needed far-field measurements, the DUT and its antenna can be oriented at will so as to take measurements in the long direction of the enclosure. Therefore, a test enclosure does not need to be constructed with far-field dimensions in each of its dimensions (height, width, depth).

Those skilled in the art will appreciate the advantage of making measurements in a test environment permitting far-field spacing between the equipment therein. The far-field dimension may be determined by the aperture (size) of the antennae, the operating frequency (or wavelength), the phasing as in an antenna array, and other known parameters. Therefore, a test enclosure can be sized and designed to suit testing of a variety of compact communication systems in known RF or other wavelength ranges.

In some aspects, the present test system is one of a plurality of such test systems in a production line testing station. It can be seen that, especially given its compact nature, the present test enclosure can be placed side by side along with a number of such enclosures so that an operator can conduct testing on a first test system while another operator conducts testing on a second test system and so on to increase the throughput of the testing facility or station.

As will be described in greater detail later, it can be seen that a controller generates the test signals sent to an internal antenna with proper shielded connections 140 to the outside environment. The source of the test signals being sent to antenna can be a computer or amplifier or master device that is placed off-site or in another room, or the test signals can come from the computer of an engineer or test operator sitting half way around the world, said signals delivered over a network connection. The same can be said for the measurements collected by the test system, which can be delivered to the controller, linker matrix module, or to any other device coupled thereto by a communication cable, fiber, or network.

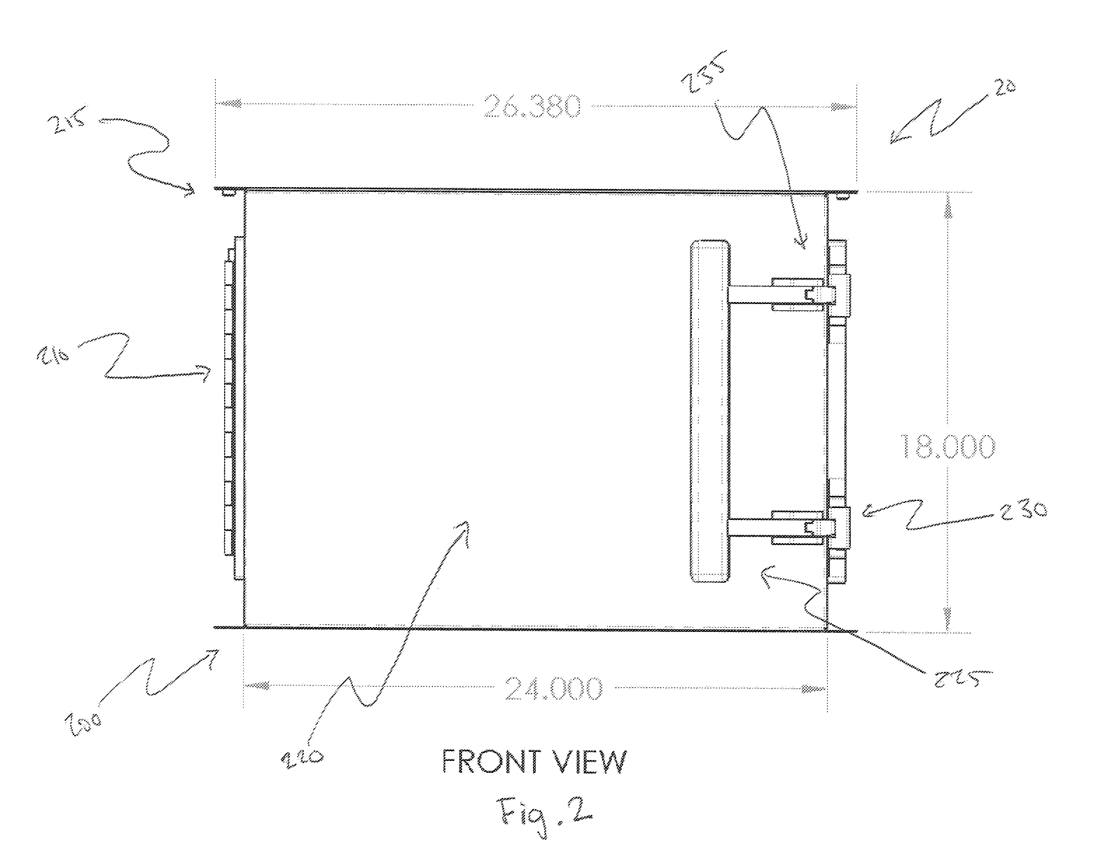

FIG. 2 illustrates a front view of an exemplary system 20 found in one or more embodiments of the present invention. Test chamber 200 includes an electromagnetic isolating door 220, which is affixed to the test chamber housing by a hinge 210. Hinge 210 acts as a pivot point for the electromagnetic isolating door 220 by which the interior of test chamber 200 can be accessed using handle 225. Electromagnetic isolating door 220 is secured to the test chamber housing by latching mechanism 235 and brackets 230 which adhere said assembly to the test chamber housing. In some embodiments brackets 230 may be bolted, welded, screwed, chemically bonded or other suitable adherence means to the test chamber 200. As will be described in greater detail later, a plurality of test chambers are arrayed in practice (wireless mesh testing). Stacking rails 215 are used to configure an array stack one on top of one another. In other embodiments within the scope of the present invention, arrays can be configured in a variety of arrangements, such as, side by side, front to back, etc. Sometimes, it is preferred to configure test chambers for the shortest electrical communication pathway, where input/output (I/O) panel, shown in proceeding figure, is disposed to face the I/O panel of an additional test chamber.

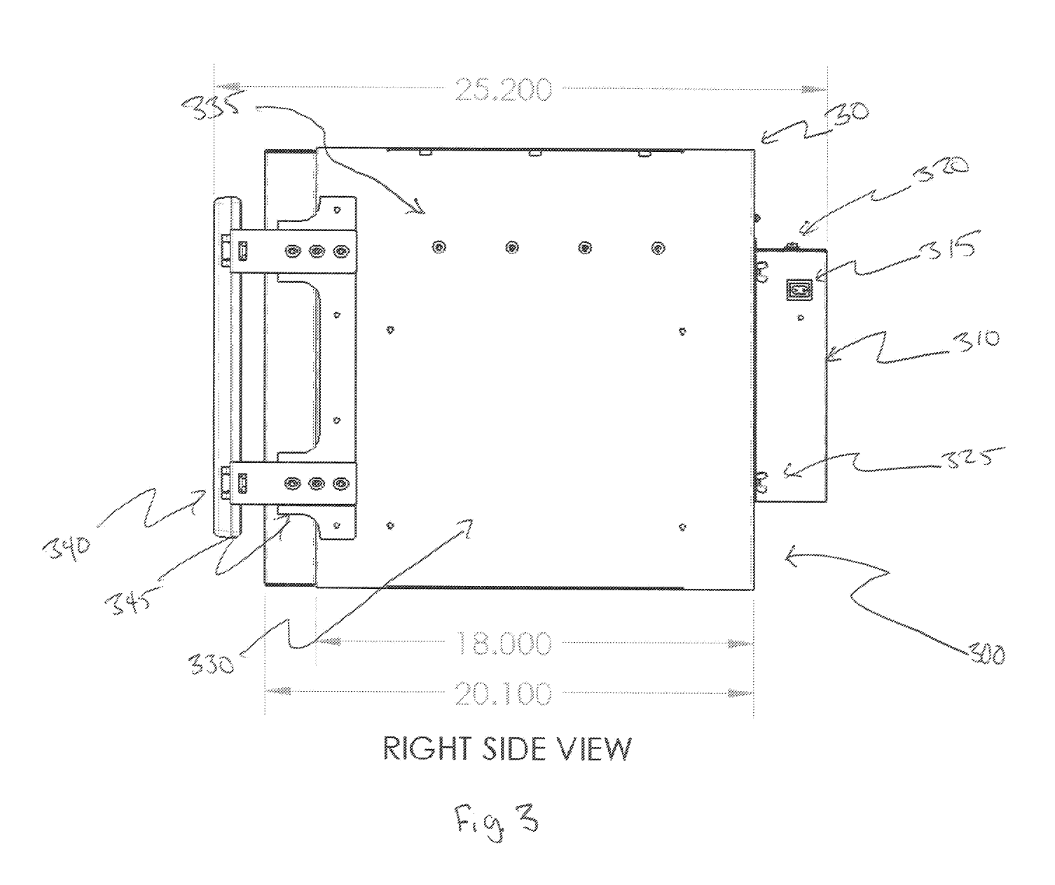

FIG. 3 is an exemplary right side view of one component, test chamber 300, within a wireless mesh testing system 30. The cavity, within which a DUT is typically disposed, is sealed by means of handle, latch 340, and bracket 345. In some embodiments, test chamber 300 includes a rear panel 310 affixed hereto using wing nuts 325 or other suitable means. Rear panel 310 may have a standard power connection with suitable filter 315 and on-off switch 320.

Referring to FIG. 3, some primary components and connections are shown as would present to an operator testing a DUT in the present enclosure systems. Some components of the system are disposed within the cavity of test chamber 300, as will be described later, while other components are disposed on the exterior of test chamber 300. As stated before, test chamber 300 materials are preferably constructed of an electromagnetically shielding or opaque material such as steel or other high conductivity metal. In some embodiments a steel box forms the basis of the frame for each of the chambers. In other embodiments, any alloy, composite, or even semiconductor (e.g., with reverse bias over depletion zone) with readily available electrons in the valence shell may be used as basis of construction.

A controller is used to generate test signals to be delivered to the DUT by a test antenna, all elucidated and depicted later. Both the DUT and test antenna are located in the test chamber 300. The test antenna also receives wireless signals from DUT so that a controller can record or operate on such signals received from the DUT. Based on received information, said controller can modify egressing signals or change the electrical communication pathway to another node within a wireless mesh testing system 30.

The equipment within separate test chambers (as in an array) are substantially isolated from electromagnetic radiation between one another, and the interior of the chambers are furthermore electromagnetically isolated from the environment outside the chambers. For this reason, cables or conducting lines such as coaxial conductor cables are used to carry signals in to and out of the shielded chambers 300 et al. when required. According to some embodiments, either one or more test chambers 300 et al. may have connection, interface, or coupling capabilities to the exterior of the enclosure through appropriately shielded and/or filtered connection points. So for example, an electrical communication panel 335 may be coupled to an external device or network or computer storage apparatus by way of a shielded and filtered coaxial line or fiber optic or other communication pathway which passes through the connection panel 335 on the side of the test chamber 300 through which the communication pathway may pass.

Specifically, in one embodiment, a coupling panel 335 may be installed in the right wall of the test chamber 300. The coupling panel 335 may have a first face proximal to or facing inward towards the interior of the chamber and a second face proximal to or facing outwards towards the exterior of the chamber. Suitable connection points, plugs, jacks, or terminator connectors are built into the inner and the outer faces of the coupling panel. Separate conducting or fiber lines or cables can be then connected to respective terminator connectors on the respective first and second faces of the coupling panel to establish communication between the inside and the outside of the chamber without directly passing a wire or line through the walls of the chamber.

To best isolate the components within test chamber 300 yet allow hard wired signaling therebetween, RF conducting cables (for example, coaxial with SMA connectors) are employed to carry signals between the antenna and controller or linker matrix module. Furthermore, to avoid leakage of unwanted or extraneous signals into the shielded test environs, the couplings are adequately shielded and filtered. A master input/output (I/O) filter and a master power filter 315 are coupled to the interior antenna by I/O and power conducting lines, respectively. The I/O and power filters are coupled to automation equipment that allows automating the present processes, in some embodiments.

An array of test chambers comprise, at least in part, a wireless mesh testing system 30 and be electromagnetically considered as a single enclosed volume. However, it may in practice be divided into a plurality of separate volumes as was described in the earlier figure. Mechanically, in other embodiments, the wireless test system 30 may be divided into two or more volumes by RF-permissive or transparent dividers, walls, shelves and so on.

In a preferred embodiment, the DUT and interior antenna are in RF communication within the test chamber 300. And, the interior antenna is in electrical communication to a combiner/attenuator. The combiner/attenuator may be electrically disposed before or after the I/O panel 335 and in electrical communication to a controller or other matrix module suitable for wireless mesh testing. Separate doors or access panels may be provided to access test chamber 300 and the antenna and/or combiner/attenuator side of the chamber 300. In this way, an operator during production can open the door to the portion of the chamber to change the antenna orientation or to swap out same without disturbing the DUT, or vice-versa.

RF feed-through connector panel 335 is used to electrically couple the RF conducting cables from the interior to exterior. Analog or digital filters may be employed within the I/O panel 335. In this manner, unsuitable frequencies may eliminated using constructed filters (e.g., low/high pass, notch, etc.), as is known in the art. All openings, seams, joints, and other apertures where electromagnetic radiation may leak is electrically and/or mechanically secured and plugged or shielded to reduce unwanted interference and minimize errors in electromagnetic field measurements within the test enclosure.

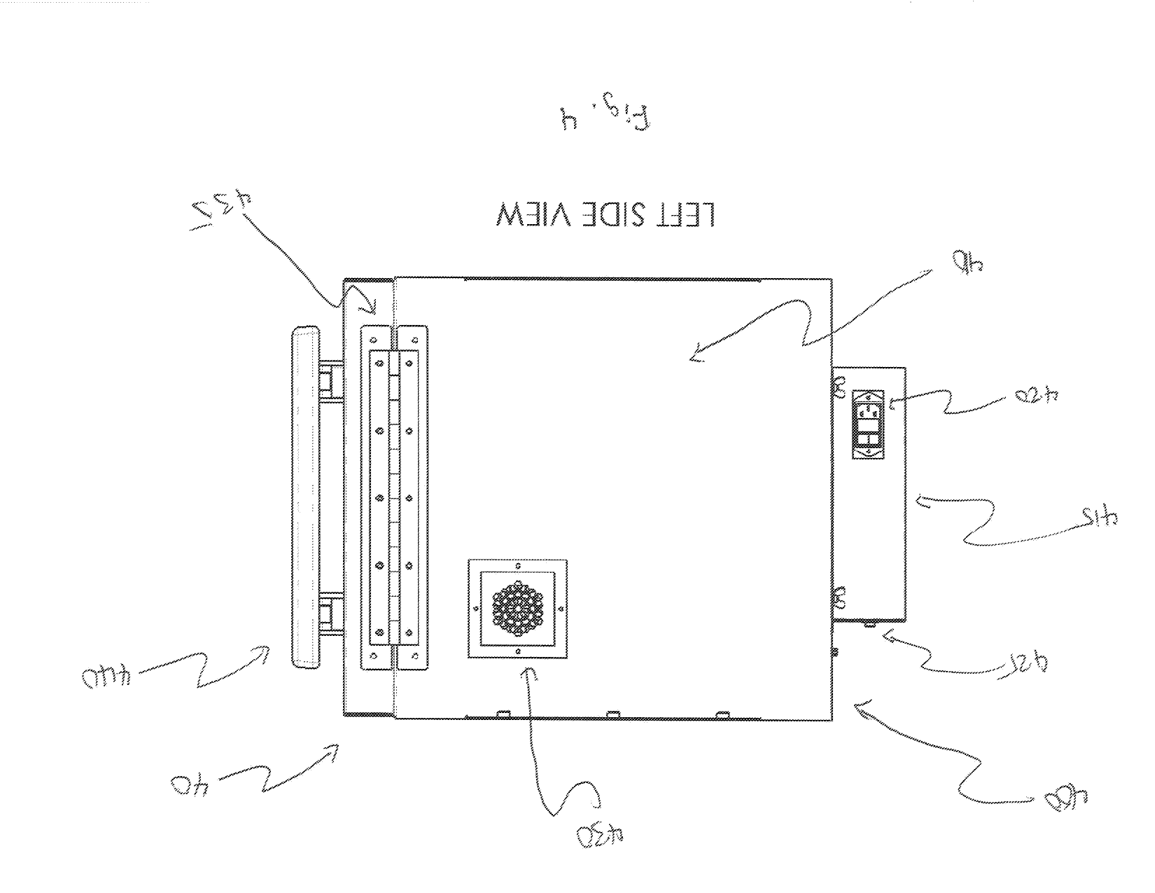

FIG. 4 illustrates an exemplary right side view of test chamber 400 as used in practice part of present wireless mesh test system 40. A right wall 410 makes up, at least in part, test chamber 400 in the present perspective. Said right wall 410 is constructed with similar anechoic electromagnetically insulated material, as previously detailed. In some embodiments, a cooling/circulatory fan 430 is disposed within the right side wall 410. As is known in the art, a screen or mesh may be employed to cover the cooling/circulatory fan 430 to attenuate wavelengths greater than half the diameter of mesh aperture size, pursuant to electromagnetic diffraction and faraday cage construction.

Some examples include a rear panel 415, on-off switch 425, and a hinge 435 to affix test chamber door 440. Rear panel 415 also includes 110V grounded power connection 420 and associated 60 Hz filter.

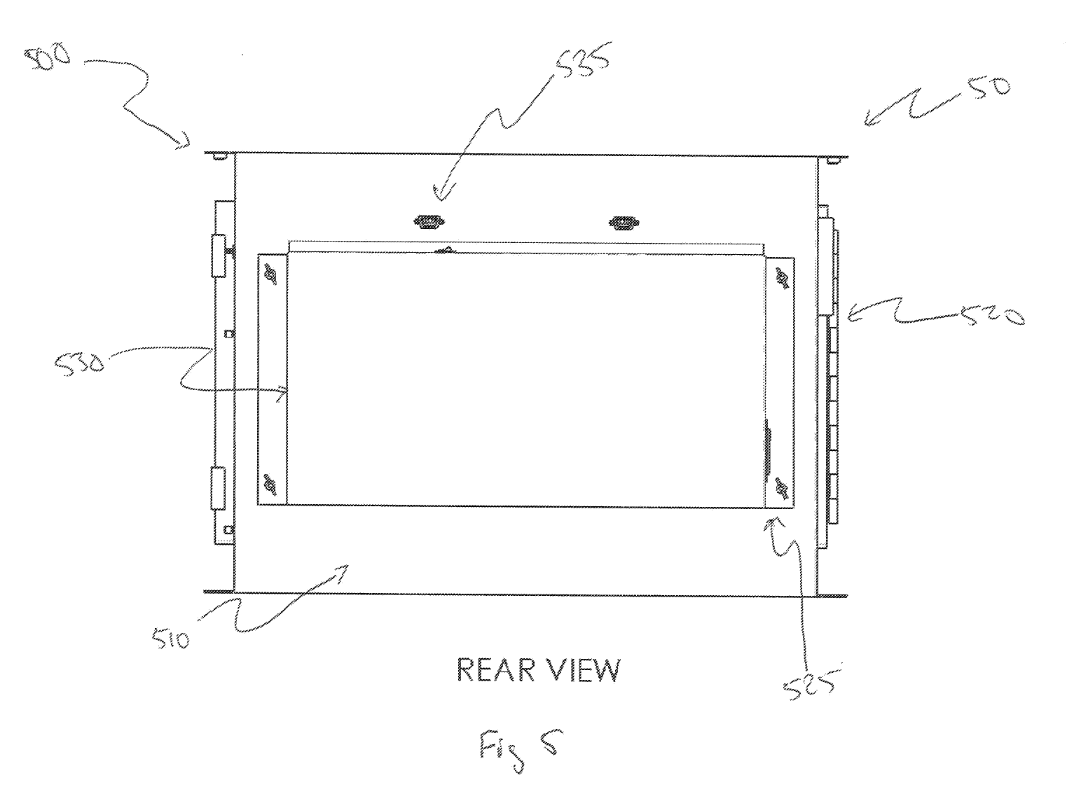

FIG. 5 illustrates an exemplary rear view is depicted of test chamber 500, as part of wireless mesh testing system 50. Previously discussed features include rear panel 530 disposed on rear wall 510 via wing nuts 525 and hinge 520. Rear wall also has electrical communication ports 535 to be used for internal control or monitoring within test chamber 500 cavity. Electrical communication ports in the present embodiment are RS232's; however, it is not outside the scope of the present invention to be some other suitable connection, digital, analog, optical or otherwise.

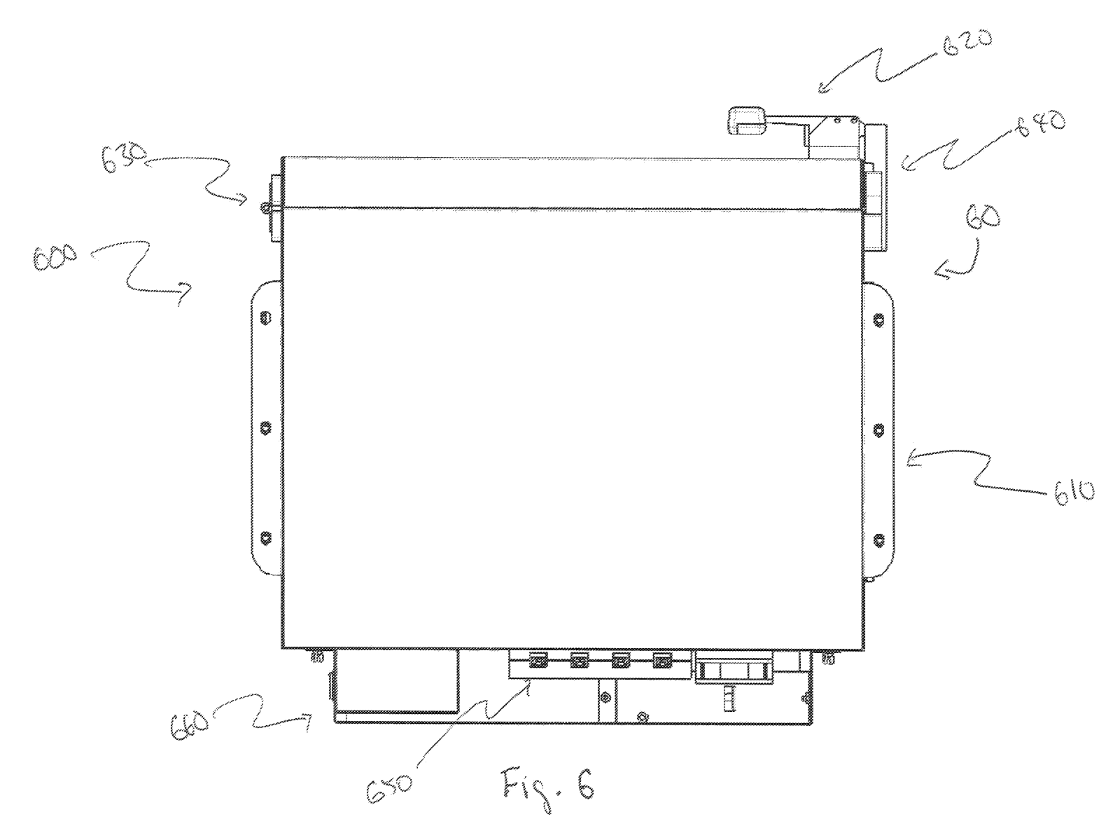

FIG. 6 illustrates a top-down exemplary perspective of test chamber 600, attention is directed to stacking rails 610 which are used to couple a plurality of test chambers as used in part of wireless mesh testing system 60. Stacking rails 610 are implemented in one embodiment as strips metal affixed to the top and bottom of test chamber 600 with drilled holes to be used to mechanically couple (that is, bolted) test chambers together. In some embodiments, stacking rails may be grommets, clamps, male/female coupling devices, or other suitable mechanical assembly.

Also shown in FIG. 6 are handle 620 used with latching mechanism 640 to secure front door 630. Rear panel 660 comprises in the present embodiment, RF I/O ports 650 and cooling fan disposed at or proximal to the rear of test chamber 600, which could be provided at or proximal to the sides of the enclosure as mentioned in previous embodiments.

FIG. 7 illustrates an exemplary view of an array of test chambers 700 used in practice as part of wireless mesh testing system 70. In a preferred embodiment, a plurality of test chambers, pursuant to previous description, are mechanically coupled together via stacking rails 720. Each test chamber serves to house a circuit node within a modeled network, as will be described in greater detail later.

Electrical communication between the electromagnetically isolated test chambers is executed by way of I/O panel ports, 740 and 750. Specifically, RF coaxial cabling with SMA connectors, not shown, is used to mechanically and electrically couple I/O panel ports, 740 and 750. In practice, any suitable conduction apparatus can be used, preferable with shielding and field termination geometries.

In some embodiments, test chambers are mechanically secured to one another by support members. The support members may be, like the shells of chambers, made of a metal such as steel. Support members can be secured to each of the first and second chambers by bolts, screws, pop rivets, welds, brazing, or other secure and suitable attachment hardware.

The interface between test chambers provides for one or more communication lines, cables, or wires (e.g., coaxial cables) to carry signals between and amongst test chambers. Such signals may include the antenna driving signal or test signals or measurement signals. A solid backing plate may be located behind the cables to protect them from mechanical damage and to further shield them from RF fields. Alternatively, a solid channel (for example a hollow rectangular-cross-sectioned channel) may be employed to run the cables through it to achieve the present goals.

Referring to FIGS. 7-9, an assembly system may be mounted on stationary mounts or legs. Alternatively, as shown, a support platform 710 may be moveable so that the system 70 can be moved from one place to another on rollers 715. Wireless mesh testing system 70 is mechanically secured to said support platform 710 with stacking rails 730 or other suitable means. The rollers 147 may comprise bearings, wheels, casters and the like to permit sliding and translational movement of the system 70 over a solid floor. In another embodiment, support legs, not shown, may be engaged into the platform 710 by threaded extensions mated to threaded portions of platform 740 to permit leveling and securing of the placement on uneven floors by proper extension of the threaded extensions.

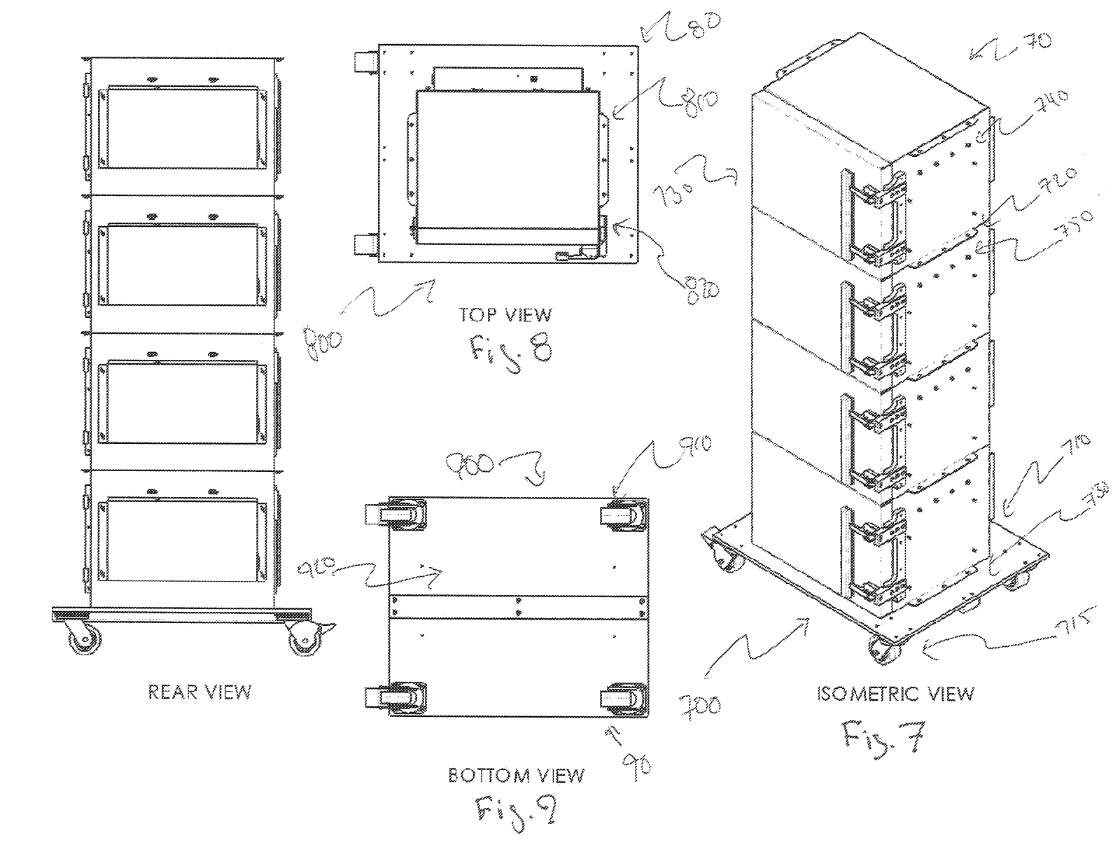

FIG. 8 illustrates an exemplary top-down perspective of a system of a plurality of test enclosures 800, which act as part of a wireless mesh testing system 80. The system of test enclosures 800 are secured to a support platform 820 by way of stacking rails 810 for ease of transportation and use in a laboratory environment.

FIG. 9 illustrates an exemplary bottom view of an array of test chambers 900, as part of wireless mesh testing system 90. As described above, array of test chambers 900 is mechanically coupled to a support platform 920. Disposed underneath said support platform, rollers 910 are used to facilitate transportation of said wireless mesh testing system.

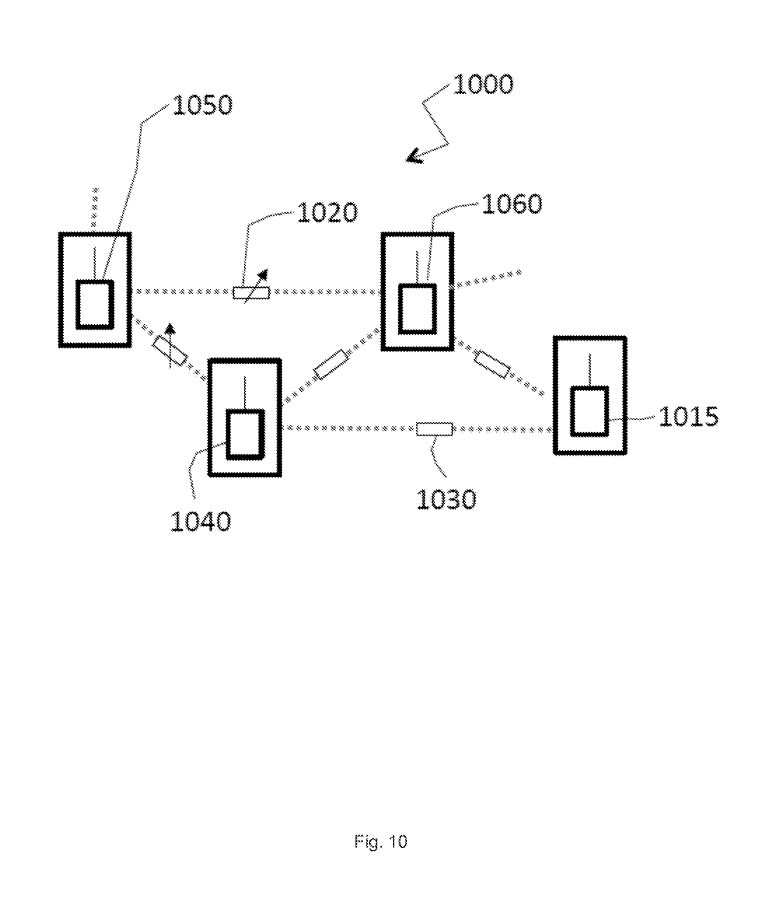

FIG. 10 illustrates a heuristic electrical block diagram for mesh testing a plurality of wireless communication devices within a controlled environment. It represents a laboratory testing platform 1010 for motion and channel emulation in an ad-hoc wireless mesh network. Reduced to practice, each of a plurality of mobile devices, 1050, 1060, 1015, and 1040 are disposed within respective test chambers, pursuant to a previously described array. As will be elucidated, each member of the electrical block diagram has a reduced-to-practice counterpart. Said electrical block diagram serves only as a didactic tool.

Turning to FIG. 10, the members of said plurality of mobile devices 1040, 1050, 1060, and 1015 are in electrical communication with one or more attenuators 1020, 1030 etc. In practice, these are implemented with RF combiners disposed in (or out of) each of the test chambers, as discussed above. Attenuators are used to emulate signal disturbances (motion, interferences, etc.) in an ad-hoc wireless environment. Changes in signal strength engenders traffic flow re-routing in the context of said wireless mesh network 1000.

Fixed attenuators 1020 et al. are used to set traffic flow through a prescribed branch or path for self-configuration and diagnosis, acting as experimental controls. Variable attenuators (i.e., rheostat or similar active or passive device) 1030 et al. are used in practice to force auto re-rerouting and to test self-healing of traffic flow within the confines of the ad-hoc network. For example, by maximizing attenuation of variable attenuator 1030, wireless mesh network 1000 is forced to re-route from network node (mobile device 1050) through network node (mobile device 1060), as opposed to nominally routing it through network node (mobile device 1040) to reach ad-hoc client (mobile device 1015).

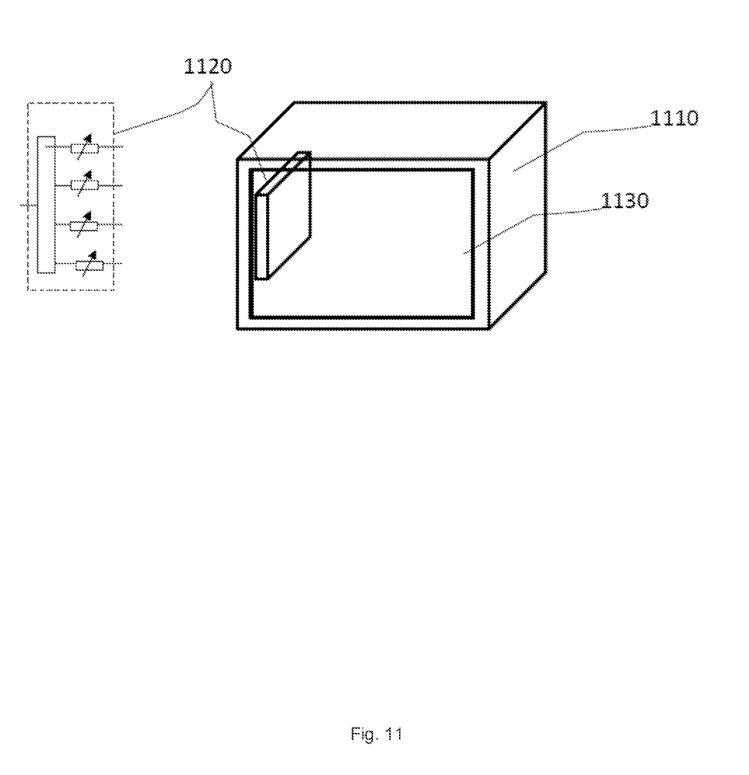

FIG. 11 illustrates an isometric view of an exemplary test chamber 1110 depicting an internal configuration with combiner/attenuator module 1120. Implementations of said combiner/attenuator modules include distributed linker matrix module, or other suitable circuit or programmable device, such as, field programmable gate array (FPGA) or pic chip. Access to the test chamber is achieved through housing aperture 1130.

In the present embodiment used in a wireless mesh network 1100, a combiner/attenuator module 1120 is disposed in the interior of each of a plurality of test chambers. Cascading electrical communications through said combiner/attenuator module 1120 amongst the test chambers is sufficient to test the re-routing and auto healing capacities of an ad-hoc network.

A preferred embodiment is composed of an exemplary arrangement of a test stations comprising a plurality of electromagnetic test chambers. The individual test chambers may be included in a communication mesh network, or “meshable” arrangement, or connected electrically through signal pathways in a mesh network arrangement, as described above. Signal pathways like those described above allow selectable passage of communication or driving or test signals between the various test chambers.

A complex system of wireless communication devices—the makeup thereof constituting an ad-hoc network—may be placed in the various chambers and tested in controlled environments as needed for a given scenario. For example, a network controller can change attenuation between nodes in order to test traffic re-routing and auto-healing capabilities.

It can be appreciated that an arbitrary number of test chambers can be coupled as described and shown. A plurality of side-by-side or stackable modular test chamber modules can be employed. Each one or group of enclosure chambers may rest on stationary or moveable base supports where they contact the laboratory floor.

Electrical quick disconnect connection lines (e.g., BNC, USB, Ethernet, coaxial or serial or parallel connections) can be used to electrically make the meshed modules in signal communication with one another while remaining substantially electromagnetically isolating as to their interior volumes. Mechanical supports and interlocking hardware can be used to fix the modules to one another in the arbitrary desired configurations, as in stacking rails.

In one or more embodiments, the present test enclosure system may be constructed to be expandable (or collapsible) in at least one dimension. Specifically, the system may include a compartment or chamber that has telescoping walls in one dimension. The system may be collapsible for compactness but may expand telescopically by slidably moving a plurality of wall sections along a direction parallel to their expanse so that the height (or width or depth) can be expanded form a first shorter size to a second longer size.

Alternatively, the system may be provided (e.g., sold) with replaceable wall sections so that the user can install a first shorter wall size if desired, but if testing larger components or longer wavelengths the user can substitute the first shorter wall section with a second longer wall section to make the testing enclosure larger in the dimension of said walls. In still other embodiments, the system may be provided in modular units that allow its user to install a desired number of modular units that stack or securely interlock with one another so that a desired dimension can be achieved.

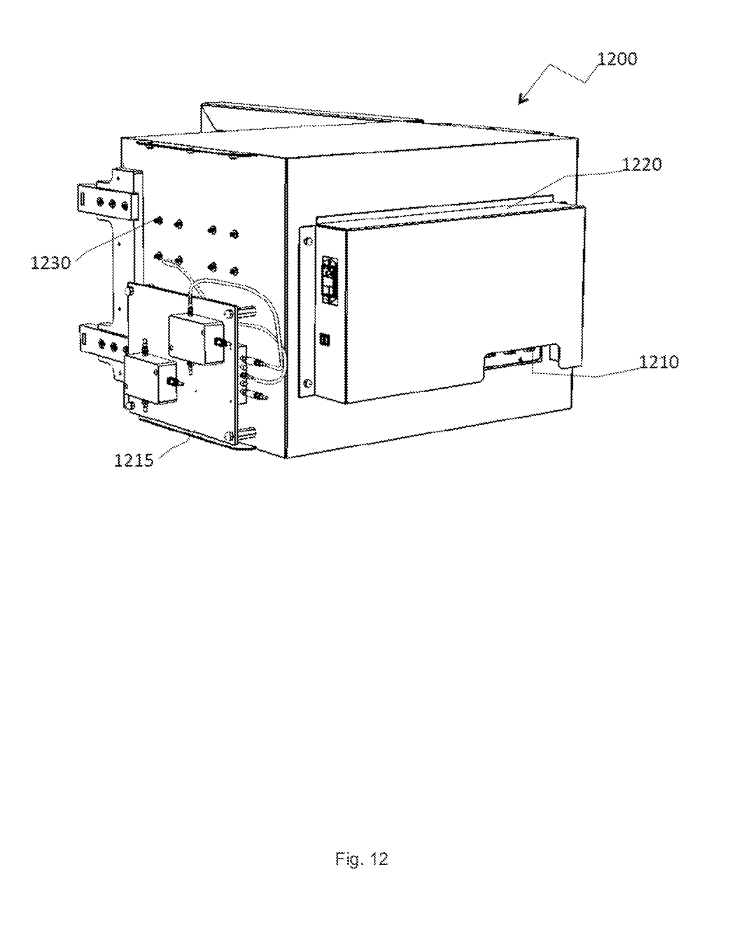

FIG. 12 illustrates an exemplary test chamber 1200 in an alternate embodiment, whereby the RF combiner/attenuator module 1215 is disposed upon the exterior of test chamber 1200. Also depicted in the present embodiment is a protective shroud 1220 covering the rear module and filtered communication port 1210 disposed above the protective shroud 1220. Typically, filtered communication port 1210 is a filtered Ethernet port, but other suitable standards and protocols are within the scope of the present invention. Adjacent to the external RF combiner/attenuator module 1215 are bulkhead SMA RF ports 1230 for I/O communication within said test chamber 1200.

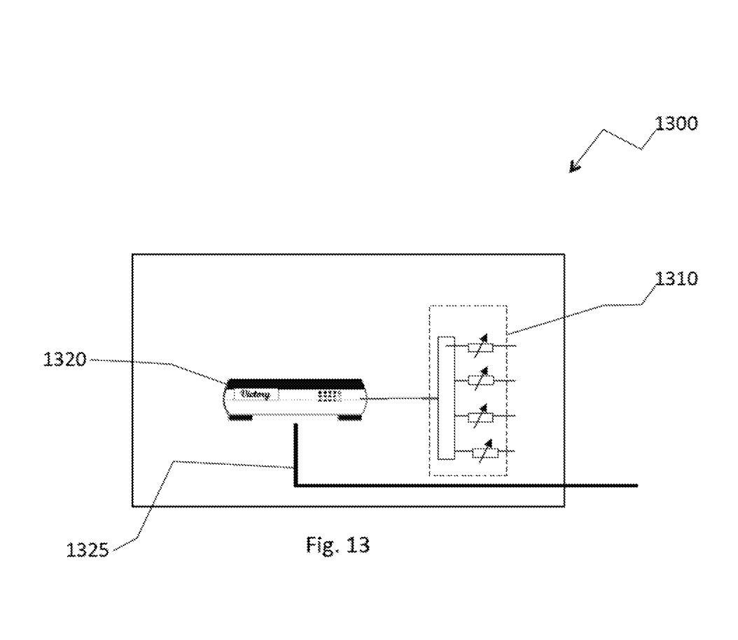

FIG. 13 illustrates an exemplary matrix module used in mesh testing system 1300, as may be implemented in one or more embodiments. Programmable controller software allows a user to configure topologies, set path loss values and reproduce field recorded fading sequences. A cascade of RF combiner/attenuator modules 1310 affords a distributed linker matrix by interconnecting mesh radios via coaxial cabling. Mesh radio 1320 may be in electrical communication with a controller via Ethernet interface 1325 and one or more combiner/attenuator modules 1310.

Optionally, in some embodiments a positioning apparatus can be disposed in each test chamber. The positioning apparatus includes one or more structural members that form a frame of the apparatus and allow other components to be fixed thereto and allow the positioning apparatus to interface with the overall device testing system. A support platform may be a rack, shelf, or other member as discussed and shown herein to support or hold the DUT or plurality of DUTs being tested. Securement of the DUT may be provided by a suitable mount, bracket, clip, or mechanical feature. A platter having one or more screw mounts or retaining elements can be used to aid in the securing and positioning of the DUT.

Rotating members, for example gears or frictional wheels are moved by way of a motor and are supported on rollers to permit rotational movement of bracket or shelf member and platter. The rotation is accomplished by a motor that is placed outside the test enclosure but is coupled by an axis or shaft and bearing.

Feedback or position detection may be provided by sensors that sense the angular or translational orientation and position of the DUT or other component of the positioning apparatus. The position is then relayed to the position controller in real time. In some embodiments, the side support members are substantially fixed to the walls of the test chamber.

One or more position controllers may be employed to control the position of a device under test (DUT) within the RF shielded enclosures and relative to other things such as the antenna described above. In a preferred embodiment or embodiments, the positioning of the DUT is performed in an automated way using computer controls.

One advantage of automated positioning is that many positions and corresponding measurements may be made, which is tedious for a human operator to accomplish with accuracy in a short time. Another advantage of automated positioning and testing is that a computer running a test program or algorithm may automatically seek certain informative and useful positions in which to place the DUTs and make corresponding measurements.

Optimization techniques and non-uniform gridding may be applied to seek positions and test cases to collect data in an automated fashion so as to determine the performance of the DUTs. Steepest descent, least steep descent and other gradient methods can also be employed to quickly and efficiently conduct the testing so that a greater throughput of products can be tested and verified in a production line environment. When the antenna patterns of the DUT products are not geometrically uniform, the present techniques are especially useful so as to map out the field sensitivity or radiative power profile of the DUT wireless communication modules and antennae.

The positioning rack may be generic to hold the one or more DUTs, but may also be customized to suit the size, shape, weight, or other dimensions of the DUTs. Electrical couplings and connections may be provided integral with the positioning rack to mate with or supply signals and power to or from the DUTs placed into the positioning rack. For example, if the DUTs include portable hand-held communication devices (e.g., cellular phones, games, PDAs, etc.) an A/C or D/C power connection may be provided to power the DUTs during testing. Other data connections and interfaces and plugs can also be provided for convenience, and may be constructed integrally with the positioning rack design.

The DUTs may be supported on the positioning rack and rest thereon by their own weight under the force of gravity, or the DUTs may be fixed to the positioning rack by way of straps, hook-and-loop tape, adhesive strips, clips, snaps, or other mechanical fixative members so that the DUTs do not slip off of or accidentally shift in their place during testing. This especially since the positioning rack may be moveable and is generally able to translate and/or rotate within the test enclosure during testing. The DUTs may also be placed into form-fitting foam or sponge or polymer forms that substantially grasp the DUTs firmly so that they are both safe from damage and controllably moveable during testing as needed.

In some testing procedures, the positioning rack system is used to translate, rotate and generally position the DUTs in three dimensions upon manual or computer-controlled instruction from a positioning control system that controls the position of the positioning rack. The positioning rack may be moved by motors, lead screws, synchros, or other prime movers in any reasonable coordinate system. In some embodiments, a X-Y-Z positioning system is used for translation of the DUTs using the positioning rack by way of computer controlled motors in each of the X, Y, Z Cartesian coordinate directions relative to an origin in the laboratory coordinate frame. Cylindrical or spherical or other coordinate systems can be used to determine the location of a DUT and control its position and movement as well.

It can be seen from the present example that some designs for an array of test enclosures are generally upright and have a relatively wide frame with a relatively compact base or footprint. In this way, it may be convenient for a standing or seated operator to access the equipment within the enclosure chambers during operation. Also, the enclosure system will require less square footage on the floor of a shop or manufacturing facility. In this way, several upright test enclosure systems may be set up near each other at a testing station employing several operators testing numerous DUT machines at the same time.

Additionally, by designing the test enclosures with an elongated dimension (e.g., width) there is ample room in the elongated dimension for achieving far-field wireless communication between the DUT and the interior antenna in the DUT chamber of the system.

It should be noted that in some aspects, the positioning system and its mechanical components are constructed of RF-compatible or electromagnetically-permeable materials such as plastic, wood, some ceramics, and some types of glass or fiber boards (natural or synthetic). This minimizes the effect of the positioning system on the measurements being made during testing and allows for a more natural simulation of the performance of the devices under test (DUTs).

The present invention should not be considered limited to the particular embodiments described above, but rather should be understood to cover all aspects of the invention as fairly set out in the attached claims. Various modifications, equivalent processes, as well as numerous structures to which the present invention may be applicable, will be readily apparent to those skilled in the art to which the present invention is directed upon review of the present disclosure. The proceeding enumeration of embodiments are intended to cover such modifications and equivalents.

What is claimed is:

1. A system for testing electromagnetic components, comprising:
a plurality of electromagnetically-isolated chambers for housing a corresponding plurality of wireless communication components;
said chambers comprising electromagnetically-isolating walls that substantially define respective interior volumes thereof;
said chambers having communication signal lines interconnecting the chambers to one another in a mesh network configuration; and
said chambers further comprising respective access ports that allow access to said respective interior volumes thereof when open and substantially isolate said respective interior volumes from external electromagnetic fields when shut.

2. The system of claim 1, said walls comprising surfaces of a lossy medium facing inwardly into said interior volumes.

3. The system of claim 1, comprising an electromagnetically-isolating envelope surrounding said first and second chambers.

4. The system of claim 1, said access ports comprising perimeter edges thereof having electromagnetically-isolating gasket material thereon to better seal said access ports when they are shut.

5. The system of claim 1, said wireless communication components comprising devices under test (DUTs) having respective antennas for over the air communication with corresponding antennas disposed in the respective test chambers.

6. The system of claim 1, further comprising a controller, said controller permitting substantially simultaneous testing of a plurality of mesh-connected devices under testing (DUTs).

7. The system of claim 1, further comprising a positioning apparatus being controllable by a microprocessor based positioning controller to position one or more of the electromagnetic components within said chambers.

8. The system of claim 1, further comprising mechanical adapters for mechanically coupling one or more chambers to one or more other chambers in a modular fashion.

9. The system of claim 1, said mechanical adapters permitting stacking of a plurality of said chambers.

10. The system of claim 1, further comprising an RF mesh radio for broadcast to said test chambers.

11. The system of claim 1, further comprising a sensor antenna for making an electromagnetic field measurement at a given spatial location.

12. The system of claim 1, further being integrated into a testing station in a production line that processes multiple devices under testing.

13. A method for operating a plurality of interconnected wireless communication devices under test, comprising:
installing a plurality of wireless communication devices into a corresponding plurality of electromagnetically-isolated test chambers;
establishing over the air (OTA) communication between each said wireless communication device and a corresponding antenna disposed in each of said test chambers containing the respective devices; and
coupling said test chambers to one another in a mesh network configuration by way of conducting signal lines running outside said test chambers and controlled by a communication controller.

14. The method of claim 13, further comprising mechanically coupling said plurality of test chambers to one another using mechanical adapters.

15. The method of claim 14, said mechanical adapters comprising brackets that secure one test chamber to an adjoining test chamber.

16. The method of claim 15, securing said test chambers to one another comprising stacking said one test chamber on top of said adjoining test chamber.
